(19) United States
(12) Patent Application Publication
(10) Pub. No.: US 2018/0163127 A1
(43) Pub. Date: Jun. 14, 2018

(54) GARNET COMPOUND AND METHOD FOR PRODUCING SAME, LIGHT EMITTING DEVICE AND DECORATIVE ARTICLE USING GARNET COMPOUND, AND METHOD OF USING GARNET COMPOUND

(71) Applicant: Panasonic Intellectual Property Management Co., Ltd., Osaka (JP)

(72) Inventors: Shozo OSHIO, Osaka (JP); Takeshi ABE, Osaka (JP)

(21) Appl. No.: 15/577,819

(22) PCT Filed: Jul. 15, 2016
(86) PCT No.: PCT/JP2016/003353

§ 371 Date: Nov. 29, 2017

(30) Foreign Application Priority Data
Jul. 22, 2015 (JP) 2015-144595

(51) Int. Cl. C09K 11/77; C01F 17/00; H01L 33/50

(52) U.S. Cl. CPC C09K 11/7774; C01F 17/0025; H01L 25/0753; C01P 2002/30; H01L 33/502

(57) ABSTRACT

A garnet compound includes a single particle or an aggregation of single particles, each single particle having a particle shape derived from a crystal structure of garnet. The garnet compound has a composition represented by a general formula:

A′₃B′₂(C′X₄)₃ (1)

(where A′, B′, and C′ are cations forming the garnet compound, and X is an anion forming the garnet compound), neither B′ nor C′ containing iron as a main component. The single particle in the garnet compound has a particle size categorized as sand in geology. The garnet compound contains lead in an amount of 1000 ppm or less.

### TECHNICAL FIELD

The present invention relates to a garnet compound and a method for producing the same, a light emitting device and a decorative article using the garnet compound, and a method of using the garnet compound.

### BACKGROUND ART

Artificially-synthesized compounds having a crystal structure of garnet (garnet compounds) are known. A representative example thereof is a phosphor represented by a general formula: Y₃Al₂(AlO₄)₃:Ce³⁺, and is used for light emitting diode illuminations (LED illuminations) (for example, refer to Patent Literature 1). Natural garnet compounds are known as precious stones.

In electronic devices such as LED illuminations, a garnet compound in a powder state of single crystal particles manufactured by a solid state reaction is used as a phosphor. In LED illuminations, a phosphor having a relatively large particle size is used in an electron tube and the like, and a central particle size of the phosphor is 10 μm to 30 μm, for example. In order to further improve the emission efficiency of the phosphor, a garnet compound is required to include a single crystal having a larger particle size.

As a method for crystal growth of a garnet compound, a flux method is known (for example, refer to Non-Patent Literature 1). In the method for growing a single crystal, suitable salt or oxide serving as a solvent (flux) is mixed with a material serving as a solute, and then heated and fused together. After the fusion, the mixture is led to a supersaturated solution state while the mixture is gradually cooled or the solvent is gradually evaporated, so as to grow the crystal of the garnet compound. The flux method can grow a single crystal with a relatively simple apparatus.

When a garnet compound not containing iron as a main component, particularly an aluminum garnet-type compound, is produced by the flux method, a lead compound (such as PbO and PbF₂) is used as flux.

### CITATION LIST

### Patent Literature

Patent Literature 1: Japanese Patent No. 3503139

### Non Patent Literature

Non-Patent Literature 1: The Japan Society of Applied Physics, “Handbook of Applied Physics”; Maruzen Publishing Co., Ltd., p. 335-337, Mar. 30, 1990

### SUMMARY OF INVENTION

As described above, the crystal growth of the garnet compound can be promoted by the flux method so as to obtain a single crystal having a large particle size. However, the flux method requires a large amount of an environmentally damaging substance, particularly a lead compound, used as flux. The flux method thus impedes production of a garnet compound having a single crystal with a larger particle size while reducing damage to the environment without iron contained as a main component.

The present invention has been made in view of the conventional problems. An object of the present invention is to provide a garnet compound and a method for producing the garnet compound causing little damage to the environment and including a single crystal with a large particle size without iron contained as a main component, a light emitting device and a decorative article using the garnet compound, and a method of using the garnet compound.

In order to solve the conventional problems, a garnet compound according to a first aspect of the present invention includes a single particle or an aggregation of single particles, each single particle having a particle shape derived from a crystal structure of garnet. The garnet compound has a composition represented by a general formula:

A′₃B′₂(C′X₄)₃ (1)

(where A′, B′, and C′ are cations forming the garnet compound, and X is an anion forming the garnet compound), neither B′ nor C′ containing iron as a main component. The single particle has a particle size categorized as sand in geology. The garnet compound includes lead in an amount of 1000 ppm or less.

A method for producing a garnet compound according to a second aspect of the present invention includes a step of reacting at least a rare earth halide-based compound containing a rare earth element and halogen with an oxide-based compound containing oxygen.

A method for producing a garnet compound according to a third aspect of the present invention includes a step of reacting at least fluoride with an alkali metal compound.

A light emitting device according to a fourth aspect of the present invention includes the garnet compound according to the first aspect.

A decorative article according to a fifth aspect of the present invention includes the garnet compound according to the first aspect as a decorative material.

A method of using a garnet compound according to a sixth aspect uses the garnet compound according to the first aspect as a decorative material or fluorescent sand.

### BRIEF DESCRIPTION OF DRAWINGS

FIG. 1 is a schematic view for explaining a light emitting device according to an embodiment of the present invention.

FIG. 2 is a perspective view schematically showing an example of a semiconductor light emitting device according to the embodiment of the present invention.

FIG. 3(a) is a cross-sectional view taken along line A-A of FIG. 2, and FIG. 3(b) is a cross-sectional view taken along line B-B of FIG. 2.

FIG. 4 is a view for explaining a method of forming a seal member in the semiconductor light emitting device.

FIG. 5 is a cross-sectional view schematically showing a decorative article according to the embodiment of the present invention. FIG. 5(a) illustrates a state in which particles of a garnet compound are fixed to a surface of a body to be decorated, and FIG. 5(b) illustrates a state in which part of the particles of the garnet compound is embedded in the body to be decorated.

FIG. 6 is a scanning electron micrograph showing a garnet compound of Example 1.

FIG. 7 is a scanning electron micrograph showing a garnet compound of Example 2.

FIG. 8 is a scanning electron micrograph showing a garnet compound of Example 3.

FIG. 9 is a scanning electron micrograph showing a garnet compound of Comparative Example 1.

FIG. 10 is a view showing an X-ray diffraction pattern of the garnet compound of Example 1.

FIG. 11 is a view showing emission spectra of the garnet compounds of Example 1 and Comparative Example 1.

FIG. 12 is a scanning electron micrograph showing a garnet compound of Example 4 after washing.

FIG. 13 is a scanning electron micrograph showing the garnet compound of Example 4 before washing.

FIG. 14 is a scanning electron micrograph showing a garnet compound of Example 5.

FIG. 15 is a scanning electron micrograph showing a garnet compound of Example 6.

### DESCRIPTION OF EMBODIMENTS

A garnet compound and a method for producing the garnet compound, a light emitting device and a decorative article using the garnet compound, and a method of using the garnet compound according to the present embodiment will be described in detail below. It should be noted that the features in the drawings are not necessarily drawn to scale, and may be arbitrarily enlarged and positioned to improve drawing legibility.

### [Garnet Compound]

The garnet compound according to the present embodiment is a compound including a single particle having a particle shape derived from a crystal structure of garnet or an aggregation of such single particles. The garnet compound has a composition represented by a general formula:

A′₃B′₂(C′X₄)₃ (1)

(where A′, B′, and C′ are cations forming the garnet compound, and X is an anion forming the garnet compound), wherein neither B′ nor C′ contains iron as a main component.

The garnet compound according to the present embodiment includes a single crystal (a primary particle) having a particle shape derived from a crystal structure of garnet. As used herein, the term “single particle” is a single crystal or one particle having a crystal grade similar to the single crystal. As used herein, the term “aggregation of single particles” is a particle aggregation including a large amount of single particles such as deposited particles, not an aggregation of about ten small pieces or particles. The “aggregation of single particles” is not a particle aggregation obtained such that small pieces or particles manufactured per lot are merely collected.

The garnet compound has the composition represented by the general formula (1). In the general formula (1), A′, B′, and C′ are cations forming the garnet compound, and X is an anion forming the garnet compound. In particular, A′ may be at least one element selected from the group consisting of alkali metal (such as Li, Na, and K), alkali earth metal (such as Ca, Sr, and Ba), a rare earth element (such as Y, La, Gd, Tb, and Lu), Mg, Mn, Fe, Co, Cu, and Bi. Namely, A′ may be at least one element selected from the group consisting of Li, Na, K, Ca, Sr, Ba, Y, La, Gd, Tb, Lu, Mg, Mn, Fe, Co, Cu, and Bi. B′ may be at least one element selected from the group consisting of alkali earth metal (such as Ca), a rare earth element (such as Sc and Y), Mg, Mn, Fe, Co, Ni, Cu, Zn, Al, V, Cr, Ga, Ru, In, Pt, Ti, Zr, Sn, Hf, Nb, Sb, Ta, and W. Namely, B′ may be at least one element selected from the group consisting of Ca, Sc, Y, Mg, Mn, Fe, Co, Ni, Cu, Zn, Al, V, Cr, Ga, Ru, In, Pt, Ti, Zr, Sn, Hf, Nb, Sb, Ta, and W. C′ may be at least one element selected from the group consisting of Li, Al, Fe, Ga, Si, Ge, P, and V. X may be at least one element selected from the group consisting of O, N, and F. The garnet compound according to the present embodiment is thus applicable to various modified examples depending on the composition.

Neither B′ nor C′ in the general formula (1) of the garnet compound according to the present embodiment contains iron as a main component. As used herein, the expression “neither B′ nor C′ contains iron as a main component” means that the atomic percentage of iron substituted for the constituent element of at least one of B′ and C′ is less than 30 atom %. The atomic percentage of iron substituted for the constituent element of at least one of B′ and C′ is preferably less than 10 atom %, particularly preferably 0 atom %.

The garnet compound according to the present embodiment is a sand-like inorganic compound, for example, and has a crystal structure of garnet. The garnet compound according to the present embodiment is particularly preferably aluminum garnet. The garnet compound according to the present embodiment preferably has a composition represented by a general formula:

A′₃B′₂(AlO₄)₃ (2)

(where A′ and B′ are cations forming the garnet compound), wherein B′ does not contain iron as a main component.

The garnet compound described above is preferably a rare earth compound such as (Y_{0.98}Ce_{0.02})₃Al₂(AlO₄)₃, particularly preferably rare earth aluminum garnet. In other words, at least one of A′ and B′ in the general formula (2) preferably contains a rare earth element. A rare earth compound has characteristics that easily allow trivalent rare earth ions, which function as an emission center of a phosphor (such as Ce³⁺, Eu³⁺, and Tb³⁺), to be contained in a crystal lattice. Such a rare earth compound thus can easily provide a garnet compound capable of emitting fluorescence. The garnet compound being rare earth aluminum garnet can easily function as a phosphor having high efficiency.

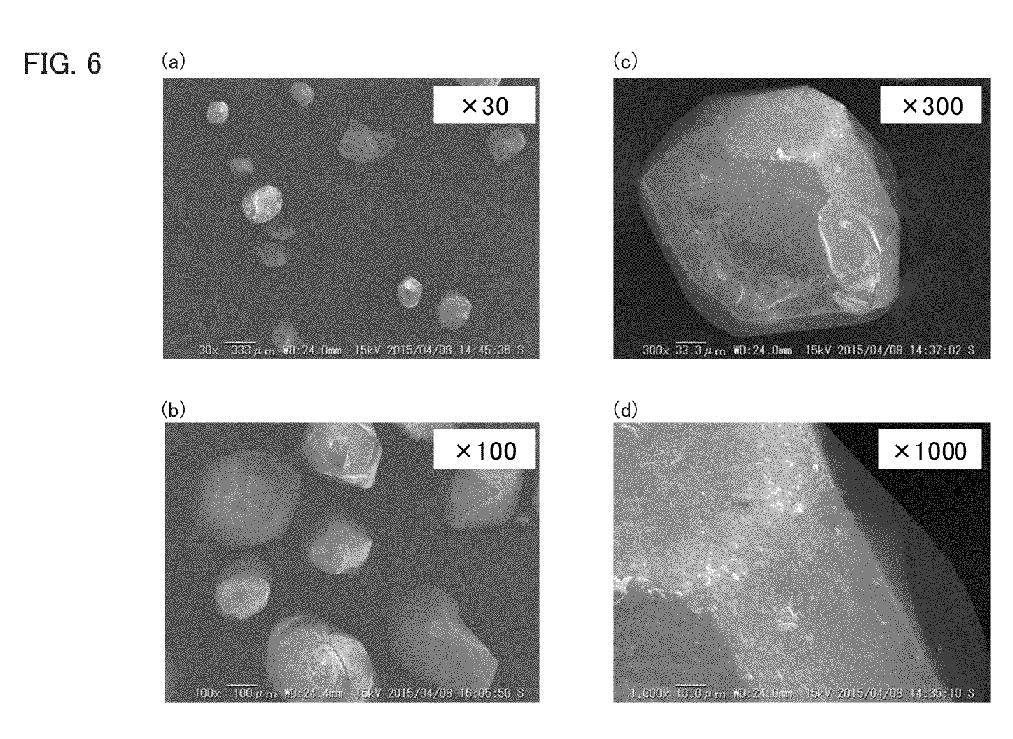

The single particle in the garnet compound according to the present embodiment has a particle size categorized as sand in geology. In particular, as shown in the electron micrographs of FIG. 6 to FIG. 8 and FIG. 12 to FIG. 15, the single particle in the garnet compound is a primary particle having a particle shape derived from a crystal structure of garnet. In FIG. 6 to FIG. 8 and FIG. 12 to FIG. 15, the particle size of the primary particle is in a range of 90 μm to 1000 μm, which is within a range of a particle size categorized as sand in geology (62.5 μm to 2 mm). It is noted that the primary particle in the garnet compound shown in FIG. 6 to FIG. 8 and FIG. 12 to FIG. 15 has not been subjected to artificial processing such as grinding or polishing.

The sand categorized in geology is divided into: very fine sand (62.5 μm to 125 μm), fine sand (125 μm to 250 μm), medium sand (250 μm to 500 μm), coarse sand (500 μm to 1000 μm), and very coarse sand (1 mm to 2 mm). The garnet compound according to the present embodiment has a particle size corresponding to sand categorized at least between very fine sand and coarse sand. Namely, the garnet compound according to the present embodiment has a particle size in a range of 62.5 μm to 2 mm, preferably in a range of 62.5 μm to 1000 μm. The garnet compound according to the present embodiment thus may be regarded as artificial sand. The particle size (the Feret diameter) of the garnet compound according to the present embodiment may be measured with a scanning electron microscope or an optical microscope.

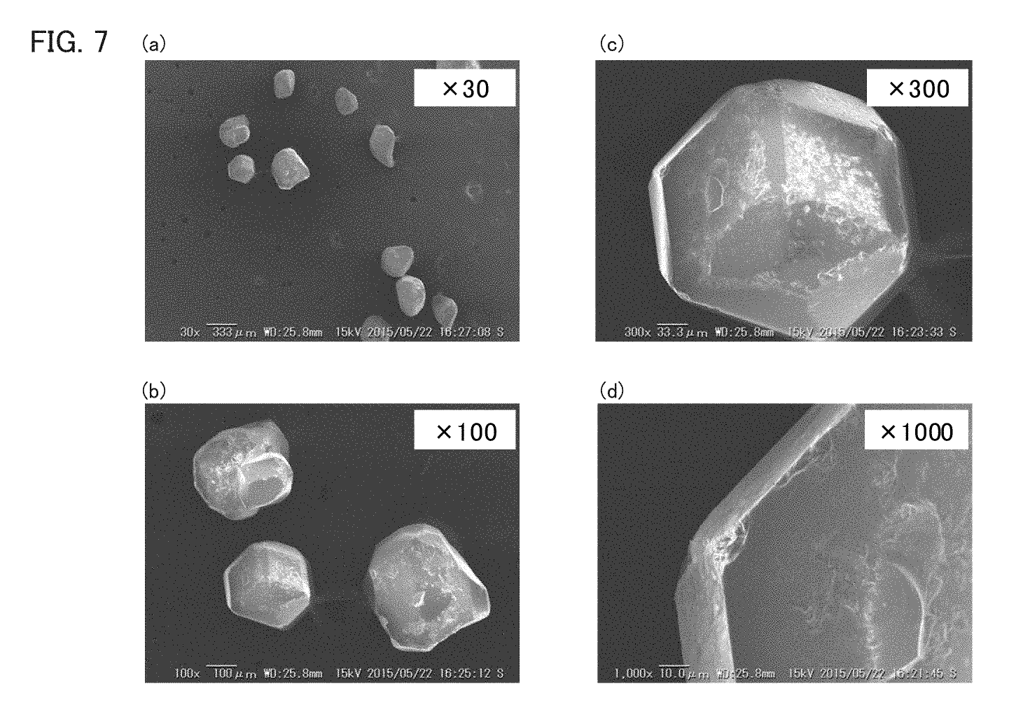

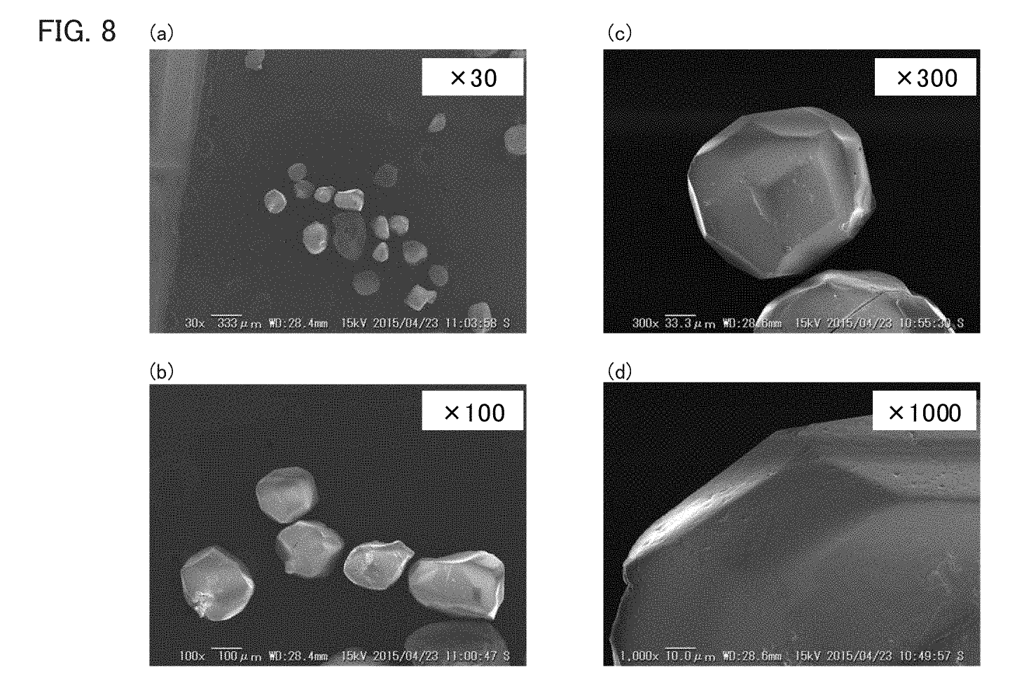

As described above, the garnet compound according to the present embodiment includes a single particle having a particle shape derived from a crystal structure of garnet or an aggregation of such single particles. In general, crystals of garnet compounds are known as having a crystal habit of a polyhedron such as a rhombic dodecahedron or a trapezohedron (particularly, trapezoidal icositetrahedron). Thus, the garnet compound according to the present embodiment preferably includes a single particle having a polyhedral particle shape derived from a crystal structure of garnet or an aggregation of such single particles. The expression “polyhedral particle shape derived from a crystal structure of garnet” is meant to encompass a polyhedron or a shape approximate to the polyhedron. The primary particle as a single particle particularly preferably has a particle shape provided with clear facets as shown in FIG. 7 and FIG. 8. The term “facets” corresponds to flat crystal faces as viewed on the atomic scale. Typically, facets are found in single crystals having a high crystal grade. As the garnet compound includes monodisperse particles having flatter facets, a particle aggregation of single crystals is regarded as having a higher crystal grade.

Even when the single particle in the garnet compound according to the present embodiment has clear facets as shown in FIG. 6, edges between adjacent facets may be rounded and thus not clearly defined. The term “polyhedral particle shape derived from a crystal structure of garnet” encompasses a particle shape of which facets and edges between the respective facets are both clearly defined. The term “polyhedral particle shape derived from a crystal structure of garnet” also encompasses a particle shape of which facets are clearly defined, while edges between the respective facets are not clearly defined.

The garnet compound having relatively high hardness, such as aluminate and silicate, is not fragile, so that the particle can be subjected to artificial processing (particularly, precision processing such as polishing). The garnet compound has a crystal habit of a rhombic dodecahedron or a trapezohedron, of which the entire shape is a polyhedron having a substantially-spherical (pseudospherical) shape. Therefore, the particle in the garnet compound according to the present embodiment can be subjected to artificial processing to have a spherical, plate-like, or cubic shape, so as to relatively easily enhance the value in industrial application. The present embodiment thus can easily provide the garnet compound including such a particle subjected to artificial processing.

The inventors of the present invention have not found any publication describing a method capable of producing a garnet compound including a single crystal having a beautiful polyhedral particle shape and a large particle size categorized as sand while not containing iron as a main component or not containing lead.

The orders and regulations regarding the environment have been increasingly complicated and diversified in recent years. The environmental regulations tend to be tightened increasingly, and the amount of impurities contained in products is required to be minimized accordingly. Under such circumstances, industrial production by an environmentally damaging method is not allowed in recent years. In addition, factories for manufacturing products such as domestic electrical appliances generally adopt procurement policies having higher safety standards than legal restrictions.

In contrast, the flux method described in Non-Patent Literature 1 should intentionally use a large amount of an environmentally damaging compound (particularly, a Pb compound). In addition, since flux is a cause of introduction of impurities, the flux method cannot avoid contamination of impurities due to flux. The flux method cannot precisely control the amount of impurities introduced either.

Metal ions (such as Pb²⁺) introduced in a crystal as impurities exert influence on the characteristics of the crystal. For example, if ions serving also as an emission center of a phosphor are contained in a crystal as impurities, a peak wavelength of emission may be shifted, or a new excitation band appears in an excitation spectrum. If a garnet compound used as a phosphor contains a large amount of such impurities, desirable light emission characteristics may not be obtained. Examples of ions interfering with the desirable fluorescent characteristics include Pb²⁺, Hg⁰, Tl⁺, Bi³⁺, Sb³⁺, Sn²⁺, Fe²⁺, Mn⁴⁺, and Cr³⁺.

Lead ions have properties which vary valences of other atoms in a crystal. The lead ions thus may deteriorate material properties such as optical characteristics and decrease reliability in the crystal containing an element which can be turned into ions having different valences (for example, Ce: Ce³⁺↔Ce⁴⁺, Fe: Fe²⁺↔Fe³⁺). If ions serving also as a deactivation center of a phosphor, such as Fe²⁺, Ni²⁺, and Co²⁺, are contained in a crystal as impurities, the emission efficiency is decreased, and desirable light emission characteristics may not be obtained accordingly.

The garnet compound according to the present embodiment can be produced, as described below, without the use of a flux method using a compound containing ions interfering with fluorescent characteristics. Thus, the amount of impurities introduced can be minimized.

The garnet compound according to the present embodiment preferably contains lead in an amount of 1000 ppm or less. Such a garnet compound causes little damage to the environment and increase reliability of safety. Further, desired light emission characteristics can easily be obtained, since the content of lead is low. In order to further reduce damage to the environment and improve the light emission characteristics, the garnet compound preferably contains lead in an amount of 100 ppm or less, more preferably in an amount of 10 ppm or less, particularly preferably in an amount of less than 1 ppm.

The garnet compound according to the present embodiment preferably contains lead and mercury both in an amount of 1000 ppm or less. Mercury is also an environmentally damaging element exerting influence on the light emission characteristics, as in the case of lead. Reducing the content of not only lead but also mercury to 1000 ppm or less can reduce damage to the environment and improve the light emission characteristics. In order to further reduce damage to the environment and improve the light emission characteristics, the garnet compound preferably contains lead and mercury both in an amount of 100 ppm or less, more preferably in an amount of 10 ppm or less, particularly preferably in an amount of less than 1 ppm.

The garnet compound according to the present embodiment preferably contains at least one element selected from the group consisting of Hg, Bi, Tl, Sb, Sn, Fe, Mn, Cr, B, Ba, Cd, Te, Se, As, Be, In, Ni, Co, and V each in an amount of 1000 ppm or less. Since Hg, Bi, and Tl which may serve as an emission center cause a lot of damage to the environment, an environment-friendly garnet compound having high reproductive performance of emission can be provided when the content of these elements is reduced. Since Sb, Sn, Fe, Mn, and Cr which may serve as an emission center are also relatively environmentally damaging elements, an environment-friendly garnet compound having high reproductive performance of emission can be provided when the content of these elements is reduced. Since B and Ba are relatively environmentally damaging elements, an environment-friendly garnet compound can be provided when the content of these elements is reduced. Since Cd, Te, Se, As, Be, In, Ni, Co, and V have a relatively high level of influence on the environment or human bodies, an environment-friendly and health-friendly garnet compound can be provided when the content of these elements is reduced.

In order to further reduce damage to the environment and influence on human bodies, the content of the elements described above is preferably reduced as much as possible. The garnet compound contains at least one element selected from the group consisting of Hg, Bi, Tl, Sb, Sn, Fe, Mn, Cr, B, Ba, Cd, Te, Se, As, Be, In, Ni, Co, and V each in an amount of 100 ppm or less. The content of each element described above in the garnet compound is more preferably 10 ppm or less, particularly preferably less than 1 ppm.

As described above, these elements contained as impurities may exert the influence not only on the environment and human bodies but also on the function as a phosphor. Thus, the lower limit of the content of at least one element selected from the group consisting of Pb, Hg, Bi, Tl, Sb, Sn, Fe, Mn, Cr, B, Ba, Cd, Te, Se, As, Be, In, Ni, Co, and V contained in the garnet compound is 0 ppm.

Inorganic compounds generally encompass a lot of modified examples. The garnet compound according to the present embodiment is also applicable to various modified examples depending on the composition within a range not impairing the crystal structure of garnet. In particular, the garnet compound according to the present embodiment can be solid-solved with the garnet compound selected from compounds listed below (especially, Y₃Al₂(AlO₄)₃) as an end-member so as to form a solid solution different from such an end-member. The solid solution to be obtained can contain a wide variety of compounds having a crystal structure of garnet. Examples of garnet compounds serving as an end-member include Y₃Al₂(AlO₄)₃, Gd₃Al₂(AlO₄)₃, Tb₃Al₂(AlO₄)₃, Lu₃Al₂(AlO₄)₃, Y₃Ga₂(AlO₄)₃, Y₃Ga₂(GaO₄)₃, Ca₃Sc₂(SiO₄)₃, Lu₂CaMg₂(SiO₄)₃, Ca₂NaMg₂(VO₄)₃, Y₃Mg₂(A₄)(SiO₄)₂, Ca₂YZr₂(AlO₄)₃, Ca₂EuZr₂(AlO₄)₃, Na₃Al₂(LiF₄)₃, Sr₃Y₂(GeO₄)₃, Fe₃Al₂(SiO₄)₃, Mg₃Al₂(SiO₄)₃, Mn₃Al₂(SiO₄)₃, Ca₃Fe₂(SiO₄)₃, and Ca₃Cr₂(SiO₄)₃.

The garnet compound according to the present embodiment may include either a transparent crystal or a colored crystal. A transparent garnet compound may be a compound having a large optical band gap without containing transition metal or lanthanoid which easily induces absorption and reflection of visible light. A colored garnet compound may be a compound containing at least one of transition metal and lanthanoid which easily induces absorption and reflection of visible light.

Examples of transition metal easily inducing absorption and reflection of visible light include titanium (Ti), vanadium (V), chromium (Cr), manganese (Mn), iron (Fe), cobalt (Co), nickel (Ni), and copper (Cu). Examples of lanthanoid easily inducing absorption and reflection of visible light include cerium (Ce), praseodymium (Pr), neodymium (Nd), samarium (Sm), dysprosium (Dy), holmium (Ho), erbium (Er), thulium (Tm), and ytterbium (Yb).

In general, a garnet compound can have a function as, for example, a phosphor, a magnetic material, a semiconductor, an insulator, or a dielectric substance depending on its composition. At the same time, a garnet compound can be prevented from having a function as a phosphor, a magnetic material, a semiconductor, an insulator, or a dielectric substance in such a manner as to change its composition. The garnet compound according to the present embodiment can also either serve as or be prevented from serving as one of these functions depending on its composition.

For example, when the garnet compound is required to have a fluorescent function, the garnet compound may be a compound serving as a phosphor (such as a garnet compound of aluminate or silicate). Alternatively, when the garnet compound is required to have a fluorescent function, the garnet compound may be a compound not impeding a function as a phosphor (such as a ferrite composition). The garnet compound may include a compound serving as a matrix of a phosphor when the garnet compound is used so as not to impede a function as a phosphor.

When the garnet compound is used as a phosphor that emits visible light, the garnet compound preferably does not contain at least one element selected from the group consisting of chromium, iron, cobalt, and nickel, each serving as ions that emit a fluorescent component in an infrared range. When the garnet compound is not intended to have a fluorescent function, the garnet compound may be a compound positively impeding a function as a phosphor or a compound containing ions impeding a function as a phosphor.

The same technical idea as in the case of determining whether to have a function as a phosphor may also be applied to the case of determining whether to have a function as a magnetic material, a semiconductor, an insulator, or a dielectric substance.

As described above, the garnet compound according to the present embodiment is a compound including a single particle having a particle shape derived from a crystal structure of garnet or an aggregation of such single particles. The garnet compound has a composition represented by the general formula:

A′₃B′₂(C′X₄)₃ (1)

(where A′, B′, and C′ are cations which may form the garnet compound, and X is an anion which may form the garnet compound), wherein neither B′ nor C′ contains iron as a main component. The single particle in the garnet compound has a particle size categorized as sand in geology. The garnet compound contains lead in an amount of 1000 ppm or less.

The garnet compound according to the present embodiment can ensure a fluorescent function with high efficiency, so as to contribute to providing a high-performance emitting device. The garnet compound containing a significantly small amount of lead can prevent damage to the environment to increase the safety. The garnet compound according to the present embodiment has a beautiful polyhedral particle shape derived from a crystal structure of garnet and inherently has high hardness. Each particle of the garnet compound has also a value as a precious stone or a polisher. Thus, the garnet compound can provide novel usage and application in addition to various kinds of decorative articles of new design.

### [Method for Producing Garnet Compound]

A method for producing the garnet compound according to the present embodiment is described below. The garnet compound according to the present embodiment can be produced in a manner such that a halide-based compound containing halogen and an oxide-based compound containing oxygen used as raw materials are reacted with each other. When the garnet compound contains a rare earth element, the garnet compound may be produced in a manner such that at least a rare earth halide-based compound containing the rare earth element and halogen and an oxide-based compound containing oxygen are reacted with each other. The production method according to the present embodiment is a method using, as a main component, a compound which is conventionally used as flux in a solid state reaction method, and different from the conventional solid state reaction method or a flux method.

In particular, the method for producing the garnet compound includes at least a step of mixing a halide-based compound containing halogen with an oxide-based compound containing oxygen, and a step of heating the mixed raw material obtained by the mixing step. The method for producing the garnet compound preferably includes a step of mixing a rare earth halide-based compound containing a rare earth element and halogen with the oxide-based compound, and a step of heating the mixed raw material obtained by the mixing step. The mixed raw material contains at least all elements composing the garnet compound.

In the mixing step, the halide-based compound and the oxide-based compound are prepared so as to have or approximate to a stoichiometric composition for a desirable garnet compound, and sufficiently mixed by use of a mortar or a ball mill. In the heating step, the mixed raw material is placed in a baking container such as an alumina crucible and baked by use of an electric furnace, for example. The mixed raw material is preferably baked in such a manner as to be heated at a baking temperature in a range of 900° C. to 1700° C., particularly preferably in a range of 1000° C. to 1400° C., for several hours in air or a low reducing atmosphere.

As described above, the garnet compound according to the present embodiment can be produced by a simple method using, as a main component, a compound which is conventionally used as flux in a solid state reaction method or a flux method. The garnet compound can relatively easily be produced by the simple production method described above because the method does not require special facilities or steps.

The halide-based compound is a compound containing at least halogen, and may be various types of halide or an acid halide. The halide-based compound may be used singly, or two or more kinds thereof may be used in combination.

When the halide-based compound is the rare earth halide-based compound, the rare earth halide-based compound contains at least fluorine, so as to facilitate the production of the garnet compound. The rare earth halide-based compound is particularly preferably rare earth fluoride.

The halide-based compound preferably contains at least one element selected from the group consisting of alkali metal, alkaline earth metal, a rare earth element, and aluminum. The halide-based compound is particularly preferably fluoride containing at least one element selected from the group consisting of alkali metal, alkaline earth metal, a rare earth element, and aluminum. The rare earth halide-based compound preferably contains a rare earth element and at least one element selected from the group consisting of alkali metal, alkaline earth metal, and aluminum.

When the halide-based compound is the rare earth halide-based compound, the rare earth halide-based compound may be complex fluoride containing a rare earth element. Such complex fluoride may be obtained such that several kinds of fluoride are reacted with each other. The several kinds of fluoride may be reacted either before the above mixing step or during the above heating step.

Examples of such halide-based compounds include NH₄F, LiF, NaF, KFMgF₂, CaF₂, SrF₂, BaF₂, ScF₃, YF₃, CeF₃, GdF₃, LuF₃, ScOF, YOF, CeOF, GdOF, LuOF, AlF₃, and GaF₃. Another example is complex fluoride such as Li₃AlF₆, Na₃AlF₆, K₃AlF₆, LiYF₄, NaYF₄, KYF₄, (Li_{0.5}Na_{0.5})YF₄, and (Li₀₅K_{0.5})YF₄. The halide-based compound may be a compound obtained such that halogen other than fluorine (such as chlorine) is substituted for part of fluorine in the above-listed halide-based compounds. The halide-based compound may also be a compound obtained such that a rare earth element other than yttrium (such as La, Gd, Tb, and Lu) is substituted for part of yttrium in the above-listed halide-based compounds.

The halide-based compound particularly preferably contains at least one element selected from the group consisting of rare earth fluoride, alkali metal fluoride, aluminum fluoride, and complex fluoride containing alkali metal. Such a halide-based compound facilitates the production of the garnet compound. Examples of complex fluorides include Li₃AlF₆ and NaYF₄. The inclusion of several kinds of alkali metal tends to increase the particle size of the garnet compound and is therefore particularly preferable, although the reason for it is not confirmed.

The oxide-based compound is a compound containing at least oxygen, and examples thereof include various types of oxide, hydroxide, carbonate, nitrate, acetate, and acid halide. Since hydroxide, carbonate, nitrate, acetate, and acid halide are turned into an oxide by heating, the garnet compound can contain these compounds as a raw material. The oxide-based compound may be used singly, or two or more kinds thereof may be used in combination.

The oxide-based compound is at least one of an oxide or carbonate, so as to facilitate the production of the garnet compound. The oxide-based compound may contain at least one element selected from the group consisting of alkali metal, alkaline earth metal, a rare earth element, and aluminum.

Examples of such oxide-based compounds include Li₂O, Na₂O, K₂O, Li₂CO₃, Na₂CO₃, K₂CO₃, MgO, CaO, SrO, BaO, CaCO₃, SrCO₃, BaCO₃, Sc₂O₃, Y₂O₃, Gd₂O₃, Lu₂O₃, and Al₂O₃. The oxide-based compound particularly preferably contains at least an alkali metal compound.

In the production method according to the present embodiment, a calcined substance obtained by the heating step tends to result in a mixture of the garnet compound and complex halide. The complex halide contains alkali metal or alkaline earth metal and a rare earth element. The complex halide has dissolution characteristics different from those of the garnet compound in solubility in water and solubility in acid. The use of the dissolution characteristics can facilitate the separation of the garnet compound from the calcined substance.

As described above, the method for producing the garnet compound according to the present embodiment uses a compound as a main component which is conventionally used as flux, so as to synthesize compounds belonging to the type of aluminum garnet. The method for producing the garnet compound according to the present embodiment particularly preferably includes a step of reacting at least fluoride with an alkali metal compound. The method also preferably includes the step of further adding an aluminum compound containing oxygen into a crystal lattice to react the compounds with each other. The method thus can easily obtain the garnet compound having a large particle size provided with facets in a manner such that the fluoride, the alkali metal compound, and the aluminum compound as necessary are reacted with each other.

Examples of fluoride include rare earth fluoride (such as YF₃ and GdF₃), aluminum fluoride (AlF₃), alkali metal fluoride (such as LiF, NaF, and KF), and alkaline earth metal fluoride (such as MgF₂, CaF₂, SrF₂, and BaF₂). Examples of alkali metal compounds include alkali metal fluoride, and carbonate of alkali metal (such as Li₂CO₃, Na₂CO₃, K₂CO₃, Li₂O, Na₂O, and K₂O). Examples of aluminum compounds containing oxygen in crystal lattices include aluminum oxide, aluminum hydroxide, and aluminum nitrate. The production method may use a single kind of each of the fluoride, the alkali metal compound, and the aluminum compound, or two or more kinds in combination.

The synthesis of the aluminum garnet compound is possible by, for example, the reaction of only yttrium fluoride and aluminum oxide at 1400° C. to 1600° C. for one to two hours according to the following reaction formula 1. The particle size of the garnet compound can further be enlarged when the reaction of another fluoride and/or alkali metal compound is induced together with the reaction of yttrium fluoride and aluminum oxide.

3YF₃+4Al₂O₃→Y₃Al₅O₁₂+3AlF₃ [Chem. 1]

As described above, the production method according to the present embodiment does not require the use of a compound, such as a lead compound, as flux having influence on the environment. The garnet compound according to the present embodiment thus can relatively easily be produced by use of the reaction of a compound used as a main component, which is conventionally used as flux.

### [Phosphor]

Next, a case in which the garnet compound according to the present embodiment is used as a phosphor is described below. The garnet compound according to the present embodiment preferably contains ions called an emission center emitting fluorescence. The garnet compound functions as a phosphor emitting fluorescence accordingly.

The garnet compound may contain any ions serving as an emission center capable of emitting fluorescence. Examples of emission centers include transition metal ions (Mn²⁺, Mn⁴⁺, Cr³⁺, Fe³⁺) and rare earth ions (Ce³⁺, Pr³⁺, Nd³⁺, Sm³⁺, Eu³⁺, Gd³⁺, Tb³⁺, Dy³⁺, Ho³⁺, Er³⁺, Tm³⁺, Yb³⁺, Eu²⁺). The garnet compound containing such an emission center can emit visible light and other electromagnetic waves.

The garnet compound as a phosphor is preferably a compound which absorbs visible light having a short wavelength of 380 nm or greater and less than 480 nm and converts the short-wavelength visible light into visible light having a longer wavelength than the short-wavelength visible light. The garnet compound is more preferably a compound which absorbs violet or blue light having a wavelength of 400 nm or greater and less than 470 nm and converts the light into visible light having a longer wavelength than the short-wavelength visible light. Such a garnet compound can radiate light that a solid-state light emitting element such as a light emitting diode emits, so as to visually recognize fluorescence. Such a garnet compound can also emit fluorescence which can visually be recognized under natural light. Accordingly, the garnet compound as a phosphor can expand the industrial applicability.

Garnet compounds containing Ce³⁺ as an emission center are known as being phosphors which absorb violet or blue light having a wavelength of 400 nm or greater and less than 470 nm and convert the violet or blue light into visible light (blue-green, green, yellow, orange, or red light) having a longer wavelength than the violet or blue light. The garnet compound according to the present invention is thus preferably a phosphor activated by Ce³⁺. Such a phosphor not only can be used for a light emitting device described below but also can provide the garnet compound with a fluorescent function, so as to exhibit decoration with a higher aesthetic value.

Conventionally, an attempt to excite phosphor particles by a laser beam has been made. However, since phosphors of conventional garnet compounds typically have a small particle size of about several μm to about 10 μm, efficient excitation of the phosphors has not been achieved even when the excitation light for radiation is condensed into about ϕ100 μm with an optical lens.

The single particle in the garnet compound according to the present embodiment has a particle size categorized as sand in geology. Namely, the particle size of the single particle in the garnet compound is in a range of 62.5 μm to 2 mm. Thus, condensed excitation light can be radiated intensively on the single particle in the garnet compound, so as to excite the garnet compound efficiently to ensure high light emitting performance.

The garnet compound according to the present embodiment can be used for fluorescent sand for research on drift sand, for example. Conventional fluorescent sand known as sand for research is produced such that fluorescent paint is applied to sand gathered from a research area of sea. Such sand has a problem of removal of the fluorescent paint, which gradually decreases fluorescent intensity to make detection difficult.

The garnet compound according to the present embodiment serving as a phosphor has high hardness and a polyhedral particle shape approximate to a sphere derived from a crystal structure of garnet. The garnet compound does not require the use of fluorescent paint, and the fluorescent function remains even if the surface of the particle peels off, so as to be used for research on drift sand for a long period of time. The present embodiment encompasses a method of researching drift sand by use of the garnet compound serving as fluorescent sand.

### [Light Emitting Device]

A light emitting device according to the present embodiment is described below. The light emitting device according to the present embodiment includes the garnet compound as a phosphor described above.

The light emitting device according to the present embodiment widely encompasses electronic devices having a light emitting function, and may be any electronic device that emits any light. The light emitting device according to the present embodiment uses at least the garnet compound serving as a phosphor, and uses fluorescence emitted by the phosphor as output light or excitation light for other phosphors.

In particular, the light emitting device according to the present embodiment uses the phosphor described above in combination with an excitation source for exciting the phosphor. The phosphor absorbs energy emitted from the excitation source and converts the absorbed energy into color-controlled fluorescence. The excitation source may be selected from a discharge device, an electron gun, a solid-state light emitting element, and the like as appropriate depending on excitation characteristics of the phosphor.

A wide variety of light emitting devices using phosphors is known, and examples thereof include a fluorescent light, an electron tube, a plasma display panel (PDP), a white light emitting diode (a white LED), a laser lighting device, and a detection device using a phosphor. In a broad sense, an illumination light source, a lighting device, and a display device each using a phosphor are also light emitting devices, and a projector including a laser diode and a liquid crystal display including an LED backlight are also recognized as a light emitting device.

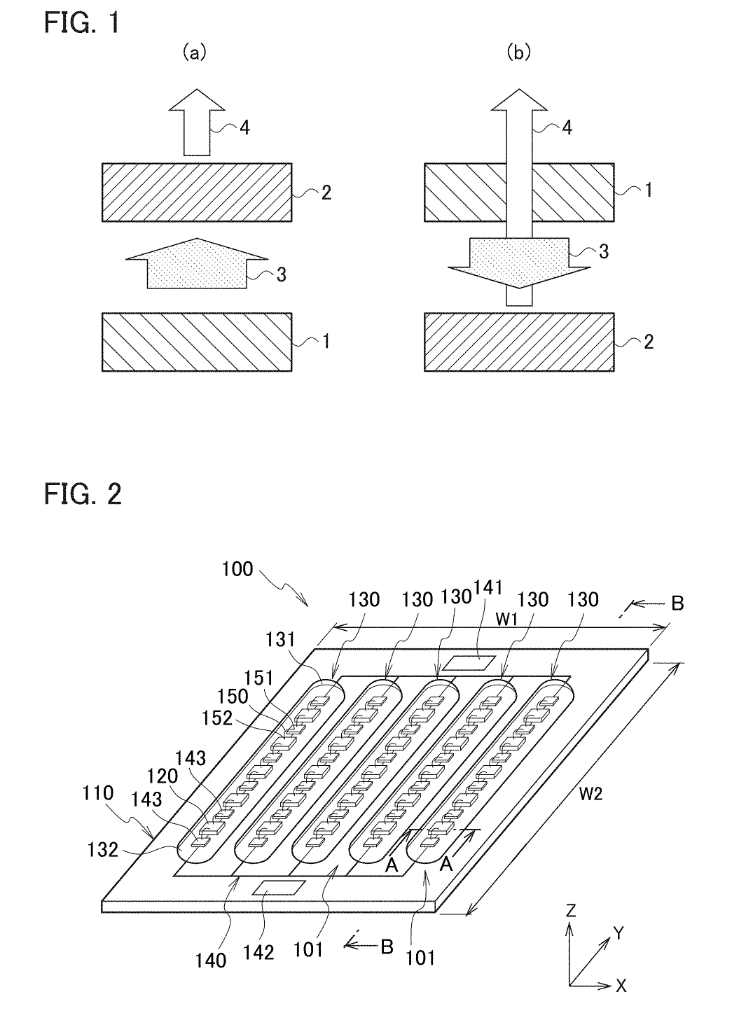

The light emitting device according to the present embodiment is described below with reference to the drawings. FIG. 1 schematically illustrates the light emitting device according to the present embodiment. In FIG. 1(a) and FIG. 1(b), an excitation source 1 is a light source for generating primary light for exciting the phosphor 2 according to the present embodiment. The excitation source 1 may be a radiation device that radiates a corpuscular beam such as an α-ray, a β-ray, and an electron beam, and an electromagnetic wave such as a γ-ray, an X-ray, a vacuum ultraviolet ray, an ultraviolet ray, and visible light (particularly short-wavelength visible light of violet light). The excitation source 1 used may be various types of radiation emitting devices, electron beam radiation devices, discharge light emitting devices, solid-state light emitting elements, and solid-state light emitting devices. Representative examples of the excitation source 1 include an electron gun, an X-ray tube, a noble gas discharge device, a mercury discharge device, a light emitting diode, a laser beam emitting device including a semiconductor laser, and an inorganic or organic electroluminescent element.

In FIG. 1(a) and FIG. 1(b), an output light 4 is fluorescence emitted from the phosphor 2 excited by the excitation light 3 or excitation beam emitted from the excitation source 1. The output light 4 is used as illumination light or display light in the light emitting device.

FIG. 1(a) illustrates the light emitting device having a configuration in which the output light 4 is emitted from the phosphor 2 in a radiating direction of the excitation beam or the excitation light 3 incident on the phosphor 2. The light emitting device shown in FIG. 1(a) may be a white LED light source, a fluorescent lamp, and an electron tube, for example. FIG. 1(b) illustrates the light emitting device having a configuration in which the output light 4 is emitted from the phosphor 2 in the opposite direction of the excitation beam or the excitation light 3 incident on the phosphor 2. The light emitting device shown in FIG. 1(b) may be a plasma display device, a light source device using a phosphor wheel provided with a reflector, and a projector, for example.

Preferable examples of the light emitting device according to the present embodiment include a semiconductor light emitting device, an illumination light source, a lighting device, a liquid crystal panel provided with an LED backlight, an LED projector, and a laser projector each using the phosphor. The light emitting device according to the present embodiment is preferably configured to excite the phosphor by short-wavelength visible light having the maximum intensity value in a range of 420 nm or greater and less than 470 nm, particularly in a range of 440 nm or greater and less than 465 nm. The light emitting device preferably further includes a solid-state light emitting element which emits short-wavelength visible light. The use of the solid-state light emitting element as an excitation source can provide an all-solid-state light emitting device having resistance to impact, such as solid-state lighting.

A lighting device using a solid-state light emitting element as a laser diode is also a preferred embodiment. The phosphor according to the present embodiment has a large particle size in a range of 62.5 μm to 1000 μm. The present embodiment thus facilitates an optical design allowing the single particle of the phosphor to absorb all laser light when the laser light is condensed to ϕ150 μm or smaller with an optical lens. Since the phosphor can be excited efficiently by use of the condensed laser light, a high-power laser lighting device can be provided.

A specific example of the light emitting device according to the present embodiment is described in detail below. As shown in FIG. 2, a semiconductor light emitting device 100 according to the present embodiment includes a substrate 110, a plurality of LEDs (light emitting elements) 120, and a plurality of seal members 130. The substrate 110 has a double-layered structure including an insulating layer formed of a ceramic substrate, heat-conductive resin, or the like, and a metal layer formed of an aluminum plate or the like. The substrate 110 has a square plate-like shape of which width W1 in the lateral direction (the X-axis direction) of the substrate 110 is in a range of 12 mm to 30 mm and width W2 in the longitudinal direction (the Y-axis direction) is in a range of 12 mm to 30 mm.

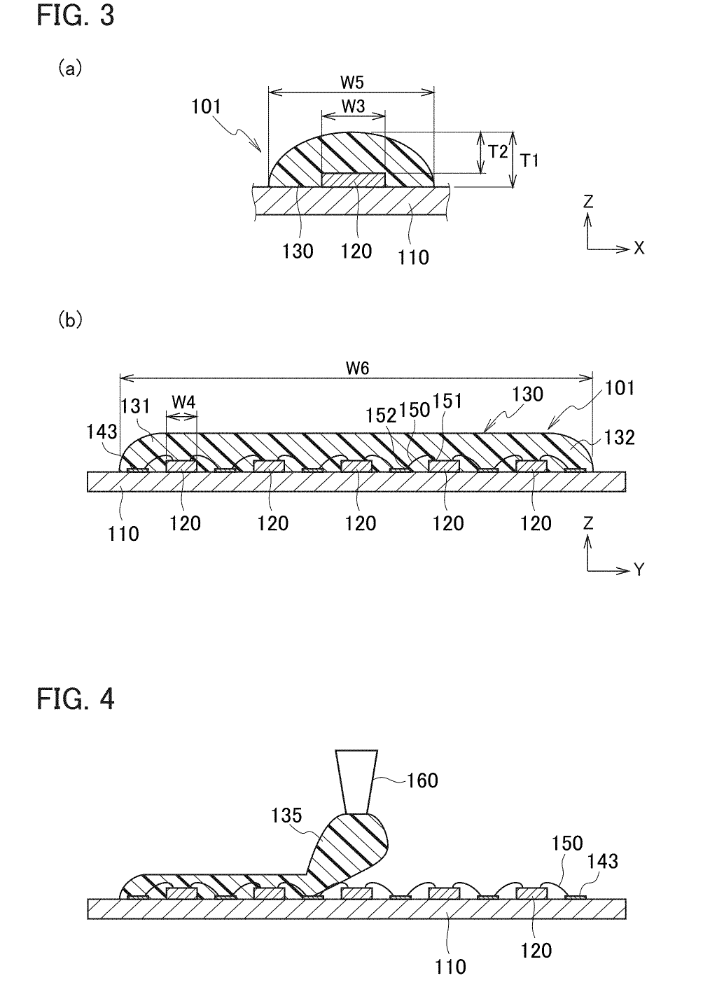

As shown in FIG. 3(a) and FIG. 3(b), the LEDs 120 are GaN-based LEDs each having a substantially rectangular shape in a plan view. Each of the LEDs 120 has width W3 in the lateral direction (the X-axis direction) in a range of 0.3 mm to 1.0 mm, width W4 in the longitudinal direction (the Y-axis direction) in a range of 0.3 mm to 1.0 mm, and a thickness (a width in the Z-axis direction) in a range of 0.08 mm to 0.30 mm.

The LEDs 120 are arranged such that an element line of the LEDs 120 conforms to the longitudinal direction (the Y-axis direction) of the substrate 110. The LEDs 120 compose the element lines for each unit of the plurality of LEDs 120 arranged in line, and a plurality of these element lines are mounted by being arrayed along the lateral direction (X-axis direction) of the substrate 110. In particular, twenty-five LEDs 120 are arranged into a matrix including five rows and five lines. In other words, five element lines, each including five LEDs, are arranged in parallel.

The LEDs 120 in each element line are aligned in the longitudinal direction (the Y-axis direction). Since the LEDs 120 are arranged straight in each line, the seal member 130 sealing the LEDs 120 can be formed straight.

As shown in FIG. 3(b), each element line is individually sealed and covered with the elongated seal member 130. A set of the element line and the seal member 130 composes a single light emitting group 101. The semiconductor light emitting device 100 thus includes five light emitting groups 101.

The seal member 130 is formed of a transparent resin material including a phosphor. Examples of resin materials include silicone resin, fluororesin, hybrid resin of silicone and epoxy resin, and urea resin. The phosphor used may be the phosphor of the garnet compound according the present embodiment. The phosphor may be not only the phosphor according to the present embodiment but also an oxide-based phosphor such as an oxide and an acid halide activated by at least one of Eu²⁺, Ce³⁺, Tb³⁺, and Mn²⁺. Alternative examples of the phosphor may be a nitride-based phosphor such as a nitride and oxynitride activated by at least one of Eu²⁺, Ce³⁺, Tb³⁺, and Mn²⁺, and a sulfide-based phosphor such as sulfide and oxysulfide.

The seal member 130 as shown in FIG. 3(a) preferably has width W5 in the lateral direction (the X-axis direction) in a range of 0.8 mm to 3.0 mm, and width W6 in the longitudinal direction (the Y-axis direction) in a range of 3.0 mm to 40.0 mm. The seal member 130 preferably has the largest thickness T1 including the LED 120 (the width in the Z-axis direction) in a range of 0.4 mm to 1.5 mm, and the largest thickness T2 excluding the LED 120 in a range of 0.2 mm to 1.3 mm. The width W5 of the seal member 130 is preferably twice to seven times as large as the width W3 of the LED 120 so as to ensure sealing reliability.

The seal member 130 has a substantially semi-elliptic shape in cross section in the lateral direction, as shown in FIG. 3(a). End portions 131 and 132 on both sides of the seal member 130 in the longitudinal direction are formed into a round shape. More particularly, the both end portions 131 and 132 have a substantially semi-circular shape in a plan view as shown in FIG. 2, and have a substantially sector-like shape having a central angle of about 90 degrees in cross section in the longitudinal direction as shown in FIG. 3(b). The seal member 130 including the end portions 131 and 132 on both sides having a round shape avoids stress concentration at the end portions 131 and 132 and facilitates the emission of light from the LEDs 120 to the outside of the seal member 130.

The respective LEDs 120 are arranged by face-up mounting. The LEDs 120 are electrically connected to a lighting circuit unit (not shown) for supplying electric power to the LEDs 120 via a wiring pattern 140 provided on the substrate 110. The wiring pattern 140 includes a pair of lands 141 and 142 for power supply, and a plurality of lands 143 for bonding arranged next to the respective LEDs 120.

As shown in FIG. 3, the LEDs 120 are electrically connected to the lands 143 via wire (such as gold wire) 150 by wire bonding. One end 151 of each piece of wire 150 is bonded to the LED 120, and the other end 152 is bonded to the land 143. Each piece of wire 150 is aligned along the element line to which the LEDs to be bonded belong. The both ends 151 and 152 of each piece of wire 150 are also aligned along the element line. The pieces of wire 150 are sealed and covered with the seal member 130 together with the LEDs 120 and the lands 143 so as to be prevented from deterioration, and are insulated to increase the safety. The LEDs 120 may be arranged on the substrate 110 by flip-chip mounting, instead of face-up mounting.

As shown in FIG. 2, five LEDs 120 are connected in series in one element line, and five element lines are connected in parallel. It is noted that the LEDs 120 are not necessarily aligned in the respective element lines and may be connected in any manner. The lands 141 and 142 are connected with a pair of lead wires (not shown) of the lighting circuit unit through which electric power is supplied to the respective LEDs 120 to emit light.

The seal member 130 may be formed by the following steps. First, as shown in FIG. 2, the substrate 110 on which a plurality of element lines each including the aligned LEDs 120 are arranged in parallel in the X-axis direction is prepared. Next, as shown in FIG. 4, resin paste 135 is linearly applied onto the substrate 110 along the respective element lines by use of a dispenser, for example. Thereafter, the applied resin paste 135 is solidified, so as to provide the seal member 130 individually along each element line.

The semiconductor light emitting device according to the present embodiment is applicable to various purposes, such as an illumination light source, a backlight of a liquid crystal display, and a light source for a display unit.

The phosphor according to the present embodiment has a larger particle size than conventional powder phosphors used for light emitting devices, so as to be a particle having a greater optical absorbing depth. The phosphor having large absorbance can provide a fluorescent film having less reflection or transmission of excitation light. The phosphor thus facilitates an increase in output performance of a light source member and a light emitting device having a configuration in which the output light 4 is emitted in the opposite direction of the excitation beam or the excitation light 3 incident on the phosphor 2, as shown in FIG. 1(b).

The phosphor according to the present embodiment has a polyhedral particle shape approximate to a sphere derived from a crystal structure of garnet, so as to provide a fluorescent film having high light transmittance. Such a fluorescent film having good efficiency of light extraction can increase the output performance of the light emitting device. The fluorescent film having good efficiency of light extraction is effectively used particularly in a configuration in which the output light 4 is emitted in the opposite direction of the excitation beam or the excitation light 3 incident on the phosphor 2, as shown in FIG. 1(b). When a reflective member is used in the light emitting device having such a configuration, the output light 4 from the phosphor 2 is reflected by the reflective member, so as to increase the output performance of the light emitting device.

The use of the garnet compound as a phosphor for a light source or the like can provide an illumination light source with high color-rendering properties and high efficiency, and provide a display unit including a screen having a wide color range with high luminance. The illumination light source may be configured such that the semiconductor light emitting device according to the present embodiment, a lighting circuit for operating the semiconductor light emitting device, and a connecting component such as a base used for connection with a lighting fixture are combined together. The illumination light source combined with a lighting fixture as necessary can provide a lighting apparatus or a lighting system.

The light emitting device according to the present embodiment exhibits high output efficiency, so as to be applicable to various purposes other than the semiconductor light emitting device and light source devices as described above.

### [Decorative Article]

A decorative article according to the present embodiment is described below. The decorative article according to the present embodiment includes the garnet compound described above as a decorative material.

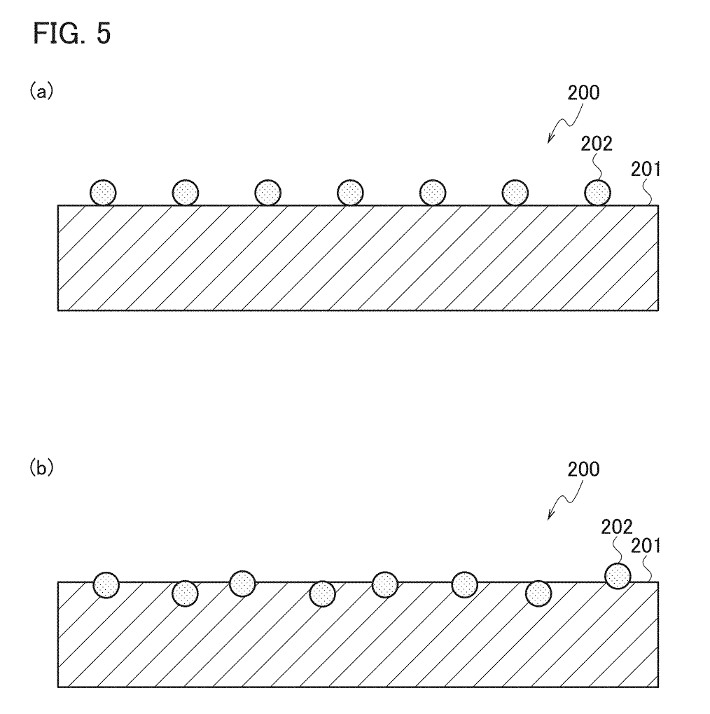

FIG. 5(a) and FIG. 5(b) schematically illustrate the decorative article 200 according to the present embodiment. In FIG. 5(a) and FIG. 5(b), a body 201 to be decorated is a substrate decorated with particles 202 of the garnet compound according to the present embodiment. The body 201 to be decorated used may be a building material, a resin product, a ceramic product, a metal product, wood, paper, and concrete, for example.

FIG. 5(a) illustrates a case in which the particles 202 of the garnet compound according to the present embodiment used as a decorative material are fixed onto the surface of the body 201 to be decorated so as to decorate the body 201 to be decorated. FIG. 5(b) illustrates a case in which the particles 202 of the garnet compound according to the present embodiment used as a decorative material are embedded in the body 201 to be decorated so as to decorate the body 201 to be decorated. As shown in FIG. 5, the decorative article according to the present embodiment is obtained such that the body 201 to be decorated is decorated with the particles 202 of the garnet compound used as a decorative material fixed onto or partly embedded in the body 201 to be decorated. The particles 202 of the garnet compound according to the present embodiment are also artificial precious stones having a size of sand, so as to provide the body 201 to be decorated with a sense of high quality and an aesthetic value.

In FIG. 5(a), the particles 202 of the garnet compound may be fixed to the surface of the body 201 to be decorated with an adhesive, for example. The fixation method used for the decorative article 200 may be any method that can fix the particles 202 of the garnet compound at least onto the surface of the body 201 to be decorated.

In FIG. 5(b), the particles 202 of the garnet compound may be partly embedded in a soft surface of the body 201 to be decorated first, and the body 201 to be decorated may be then hardened as necessary. Alternatively, the body 201 to be decorated may be prepared by use of a precursor thereof preliminarily mixed with the particles 202 of the garnet compound, and the surface of the body 201 to be decorated thus prepared may be subjected to surface treatment, so that part of the particles 202 is exposed on the surface of the body 201 to be decorated. The embedding method used for the decorative article 200 may be any method that can partly embed the particles 202 of the garnet compound at least in the body 201 to be decorated.

FIG. 5(a) and FIG. 5(b) each illustrate the case in which predetermined part of the surface of the body 201 to be decorated is decorated with the particles 202 of the garnet compound. It is noted that the surface of the body 201 to be decorated may be entirely decorated with the particles, or may be locally decorated with the particles in several portions. FIG. 5(a) and FIG. 5(b) each illustrate the case in which predetermined part of the surface of the body 201 to be decorated is decorated with the particles 202 of the garnet compound dispersed in a regular manner. It is noted that the surface of the body 201 to be decorated may be decorated with the particles 202 of the garnet compound such that the particles 202 are unevenly dispersed or locally concentrated. Alternatively, the surface of the body 201 to be decorated may be decorated with a layer of the particles 202 of the garnet compound deposited thereon.

FIG. 5(b) illustrates the case in which the particles 202 of the garnet compound project unevenly from the surface of the body 201 to be decorated. Alternatively, the particles 202 of the garnet compound may project from the surface of the body 201 to be decorated at a constant rate.

The decorative article 200 according to the present embodiment may be any object that uses a single particle of the garnet compound according to the present embodiment or an aggregation of such particles as a decorative material. The decorative article according to the present embodiment may be a building material, a resin product, a ceramic product, and a metal product, for example, each decorated with a single particle of the garnet compound or an aggregation of such particles. Other examples of the decorative article decorated with the garnet compound include a machine tool, an electric instrument, a transportation instrument, a road member, a traffic member, a coating agent, an art work, a craft work, stationery, and personal belongings. The decorative article may be a copyrighted work such as a sand painting created by use of the garnet compound.

As described above, the garnet compound according to the present embodiment has a beautiful polyhedral particle shape derived from a crystal structure of garnet, and has a relatively large particle size. The garnet compound also has a value as an artificial precious stone. Thus, a building material, a resin product, a ceramic product, a metal product, a machine tool, an electric instrument, a transportation instrument, a coating agent, an art work, a craft work, stationery, personal belongings, and the like, decorated with the garnet compound according to the present embodiment, are provided with an aesthetic value. In addition, since nails and part of bodies may be decorated, the garnet compound according to the present embodiment is applicable to nail art. Further, several kinds of garnet compounds may be used for a decorative article and a decoration method, so as to provide the decorative article with a higher aesthetic value.

As described above, the present embodiment relates to a method of using the garnet compound as a decorative material or fluorescent sand. The present embodiment also relates to a method of decorating a body to be decorated with a single particle of the garnet compound or an aggregation of such particles. Therefore, the decorating method may be regarded as a method of decorating any of a building material, a resin product, a ceramic product, a metal product, a machine tool, an electric instrument, a transportation instrument, a coating agent, an art work, a craft work, stationery, personal belongings, and nails. The present embodiment thus facilitates various kinds of decoration capable of providing an aesthetic value.

### EXAMPLES

The present embodiment will be described in more detail below with reference to examples and comparative example, but is not intended to be limited to those examples.

A phosphor as a garnet compound was synthesized in each of Examples and Comparative Example by a preparation method by use of a solid state reaction, and characteristics of the phosphor thus obtained were evaluated. In the respective Examples and Comparative Example, the following chemical powder was used as a raw material or a reaction accelerator, and the respective raw materials were weighed and mixed in the respective ratios shown in Table 1.

Yttrium oxide (Y₂O₃): purity 4N, manufactured by Shin-Etsu Chemical Co., Ltd.

Yttrium fluoride (YF₃): purity 3N, manufactured by Kojundo Chemical Laboratory Co., Ltd.

Gadolinium fluoride (GdF₃): purity 3N, manufactured by Kojundo Chemical Laboratory Co., Ltd.

Cerium oxide (CeO₂): purity 4N, manufactured by Shin-Etsu Chemical Co., Ltd.

Cerium fluoride (CeF₃): purity 3N, manufactured by Wako Pure Chemical Industries, Ltd.

Aluminum oxide (θ-Al₂O₃): purity 4N5, manufactured by Sumitomo Chemical Company, Limited

Aluminum fluoride (AlF₃): purity (no indication), manufactured by Wako Pure Chemical Industries, Ltd.

Lithium carbonate (Li₂CO₃): purity 3N5, manufactured by Kanto Chemical Co., Inc.

Sodium Carbonate (Na₂CO₃): purity 2N8, manufactured by Wako Pure Chemical Industries, Ltd.

Potassium carbonate (K₂CO₃): purity 2N5, manufactured by Kanto Chemical Co., Inc.

TABLE 1

| | Li₂CO₃ | Na₂CO₃ | K₂CO₃ | Al₂O₃ | AlF₃ | CeF₃ | YF₃ | GdF₃ | Y₂O₃ | CeO₂ |
|---|---|---|---|---|---|---|---|---|---|---|
| | (g) | (g) | (g) | (g) | (g) | (g) | (g) | (g) | (g) | (g) |
| Examples | 0.1847 | 0.265 | — | 0.1782 | 0.3501 | 0.0099 | 0.3575 | — | — | — |
| 1 to 4 | | | | | | | | | | |
| Example 5 | 0.1847 | 0.265 | — | 0.1782 | 0.3501 | 0.0099 | 0.248 | 0.1607 | — | — |
| Example 6 | 0.1847 | 0.265 | — | — | 0.3501 | 0.0099 | 0.3575 | — | — | — |
| Comparative | — | — | 0.0035 | 0.6683 | 0.0063 | — | — | — | 0.5509 | 0.0258 |
| Example 1 | | | | | | | | | | |

### Example 1

A garnet compound to be obtained in Example 1 was “(Y_{0.98}Ce_{0.02})₃Al₂(AlO₄)₃” having a garnet-type crystal structure.

The raw materials of the garnet compound were weighed in the mixing ratios shown in Table 1. The raw materials weighed were mixed in a dry process by use of a mortar and a pestle to obtain a raw material to be baked. The raw material thus obtained was placed into an alumina crucible having a lid and subjected to main baking with a box-shaped electric furnace in air at 1200° C. for two hours. A heating rate and a cooling rate were both set at 400° C./hour.

When the baked product after the main baking was visually observed, yellow fluorescent particles having a size of sand were dispersed in a white solidified product, although the indication of the data thereof is omitted herein. When a crystalline substance in the solidified product was analyzed by X-ray diffractometry, the crystalline substance was recognized as being a mixture of at least the garnet compound, a complex halide of alkali metal and a rare earth element, and aluminum oxide. The garnet compound was Y₃Al₂(AlO₄)₃ containing Ce, and the complex halide was a compound having the same crystal structure as NaYF₄.

The baked product after the main baking was then lightly grinded with the mortar and the pestle and then subjected to aftertreatment, so as to separate the garnet compound in the baked product.

In particular, the baked product after the main baking and pure water were placed in a glass beaker, and then stirred for six hours with a magnetic stirrer. The suspension generated by the stirring was completely removed through several steps, so as to obtain the garnet compound as a precipitate in the water. The precipitate thus obtained was then filtrated and dried. The garnet compound of Example 1 was thus obtained.

### Example 2

A garnet compound to be obtained in Example 2 was also “(Y_{0.98}Ce_{0.02})₃Al₂(AlO₄)₃” having a garnet-type crystal structure. The garnet compound was obtained in the same manner as Example 1 except that the time for the main baking was changed to 40 minutes.

When the baked product after the main baking in Example 2 was visually observed, yellow fluorescent particles having a size of sand were dispersed in a white solidified product, as in the case of Example 1. When a crystalline substance in the solidified product was analyzed by the X-ray diffractometry, the crystalline substance was recognized as being a mixture of at least the garnet compound, a complex halide of alkali metal and a rare earth element, and aluminum oxide. The garnet compound thus obtained was Y₃Al₂(AlO₄)₃ containing Ce, and the complex halide was a compound having the same crystal structure as NaYF₄.

### Example 3

A garnet compound to be obtained in Example 3 was also “(Y_{0.98}Ce_{0.02})₃Al₂(AlO₄)₃” having a garnet-type crystal structure.

The fluorescent raw materials were weighed and mixed to obtain a raw material to be baked in the same manner as Example 1. The raw material thus obtained was subjected to main baking in air at 1200° C. for two hours in the same manner as Example 1. The baked product after the main baking was then subjected to reduction treatment by further baking in a tubular electric furnace in a weak reduction atmosphere at 1200° C. for two hours. The weak reduction atmosphere was a mixed gas atmosphere of 96% of nitrogen and 4% of hydrogen in which the flow rate of the mixed gas was set at 100 ml/min. The baked product was then subjected to aftertreatment in the same manner as Example 1, so as to obtain the garnet compound of Example 3.

When the baked product after the reduction treatment in Example 3 was visually observed, yellow fluorescent particles having a size of sand were dispersed in a white solidified product, as in the case of Example 1. When a crystalline substance in the solidified product was analyzed by the X-ray diffractometry, the crystalline substance was recognized as being a mixture of at least the garnet compound, a complex halide of alkali metal and a rare earth element, and aluminum oxide. The garnet compound thus obtained was Y₃Al₂(AlO₄)₃ containing Ce, and the complex halide was a compound having the same crystal structure as NaYF₄.

### Comparative Example 1

In Comparative Example 1, a garnet compound of “(Y_{0.98}Ce_{0.02})₃Al₂(AlO₄)₃” having a garnet-type crystal structure was prepared by a method by use of a conventional solid state reaction.

The respective raw materials (yttrium oxide, cerium oxide, and aluminum oxide) and a reaction accelerator (aluminum fluoride and potassium carbonate) were weighed at the ratios shown in Table 1. These raw materials and the reaction accelerator were sufficiently mixed with an appropriate amount of pure water by a wet process with a ball mill. The mixed raw material was placed into a container, and dried overnight by use of a drier at 120° C. The dried raw material was grinded with the mortar and the pestle, so as to prepare a raw material to be baked.

The raw material to be baked was placed into an alumina crucible having a lid, and baked in a tubular electric furnace in a weak reduction atmosphere at 1500° C. for two hours. The weak reduction atmosphere was a mixed gas atmosphere of 96% of nitrogen and 4% of hydrogen in which the flow rate of the mixed gas was set at 100 ml/min. The garnet compound of Comparative Example 1 was thus obtained.

[Observation with Electron Microscopy]

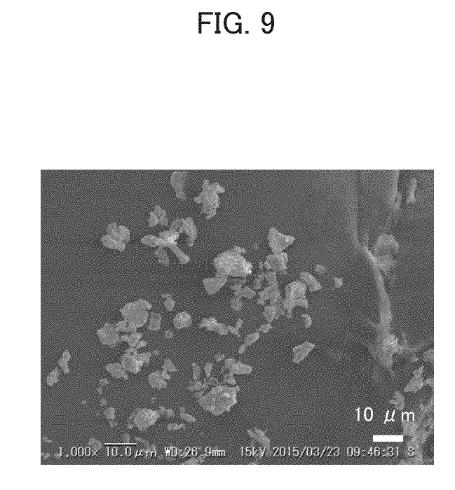

The garnet compounds obtained in Examples 1 to 3 and Comparative Example 1 were observed with an electron microscope (trade name: VE-9800, available from Keyence Corporation). FIG. 6 shows the garnet compound after washing in Example 1, FIG. 7 shows the garnet compound after washing in Example 2, FIG. 8 shows the garnet compound after washing in Example 3, and FIG. 9 shows the garnet compound in Comparative Example 1.

As apparent from the electron micrographs of Examples 1 to 3 shown in FIG. 6 to FIG. 8 and the electron micrograph of Comparative Example 1 shown in FIG. 9, the garnet compounds of Examples 1 to 3 had a particle size of 200 μm to 300 μm, while the garnet compound of Comparative Example 1 had a particle size of several μm to 10 μm.

As apparent from FIG. 6 to FIG. 8, the garnet compounds of Examples 1 to 3 were particles having a particle shape approximate to a rhombic dodecahedron which is a crystal habit of a garnet compound and provided with clear facets. The garnet compounds of Examples 1 to 3 were each an aggregation of monodisperse single particles.

### [Analysis of Crystal Structure]

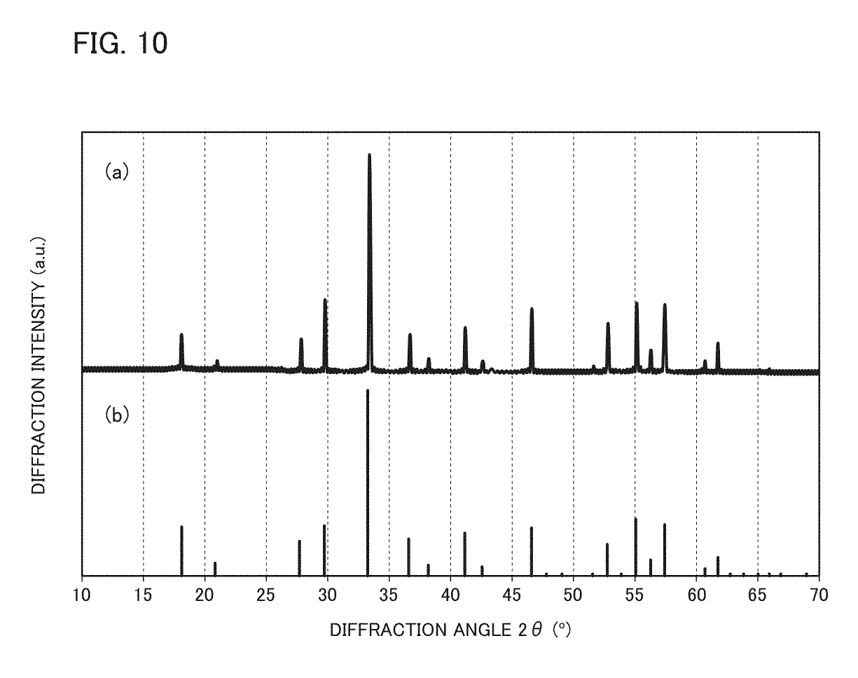

The crystal structures of the garnet compounds of Examples 1 to 3 were analyzed with an X-ray diffractometer (trade name: MultiFlex, available from Rigaku Corporation). FIG. 10 shows the measurement results. Since the analysis of the crystal structures of the garnet compounds of Examples 1 to 3 did not show any significant difference between the respective X-ray diffraction patterns, FIG. 10 shows the X-ray diffraction pattern (a) of Example 1. FIG. 10 also shows a pattern (b) of Y₃Al₅O₁₂ having a garnet-type crystal structure registered in the Powder Diffraction File (PDF) (PDF No. 33-0040).

As apparent from the comparison between the patterns (a) and (b) shown in FIG. 10, the X-ray diffraction pattern of the garnet compound of Example 1 conforms to the pattern of Y₃Al₅O₁₂ having a garnet-type crystal structure. Analysis revealed that at least the garnet compound of Example 1 mainly contains the compound having a garnet-type crystal structure.

### [Measurement of Emission Spectrum]

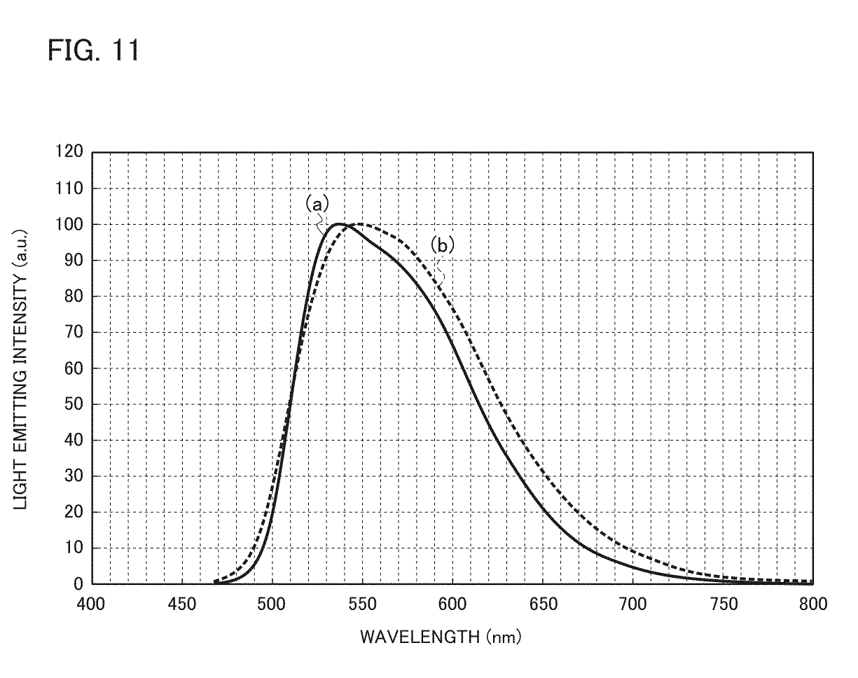

An emission spectrum when the garnet compound of Example 1 was excited by blue light was evaluated with an instantaneous multichannel photodetector system (QE-1100, available from Otsuka Electronics Co., Ltd.). The excitation wavelength during the measurement of the emission spectrum was set at 450 nm. FIG. 11 shows an emission spectrum (a) as a measurement result. FIG. 11 also shows an emission spectrum (b) of the garnet compound of Comparative Example 1 measured simultaneously.

As shown in FIG. 11, the emission spectrum of the phosphor of Example 1 has an emission peak wavelength which appears around 536 nm, and has a broad fluorescent component due to Ce³⁺. The emission spectrum of Comparative Example 1 has an emission peak wavelength which appears around 550 nm, resulting in a difference of 14 nm from the emission peak wavelength of Example 1. This is because the Ce³⁺ activation amount actually used in the garnet compound is reduced by about one digit in Example 1 with respect to the Ce³⁺ activation amount prepared (2 atom % on a Y substitution rate basis), although the details thereof are omitted herein.

### [Analysis of Impurities]

Impurities in the garnet compound of Example 1 were measured by ICP mass spectrometry (ICP-MS). The analysis method is as follows, and Table 2 summarizes the analysis results.

<Sample Pretreatment>

A mixed liquid such as sulfuric acid is added to 0.1 g of a sample, and heated and decomposed with microwaves under high pressure, and thereafter, the volume is fixed with pure water.

<Qualitative Order Analysis>

Apparatus used: Agilent 7700 series (available from Agilent Technologies)

Measurement mode: Helium collision mode

Measurement method: Quantitative concentration calculation by use of relative sensitivity factors of software belonging to apparatus

As apparent from Table 2, the amount of the respective environmentally damaging elements contained in the garnet compound of Example 1 was less than 1 ppm which is below the quantitative lower limit in the ICP mass spectrometry. In particular, the amount of each of Pb and Hg contained in the garnet compound of Example 1 was less than 1 ppm.

TABLE 2

| | Content | | Content | | Content |
|---|---|---|---|---|---|
| Element | [μg/g] | Element | [μg/g] | Element | [μg/g] |
| Li | 3.00E+02 | Se | <0.1 | Sm | <0.01 |
| Be | <1 | Br | <0.1 | Eu | 0.2 |
| B | <1 | Rb | <0.1 | Gd | 0.5 |
| Na | 7.00E+02 | Sr | 2 | Tb | 0.9 |
| Mg | 6 | Y | * | Dy | <0.01 |
| Al | * | Zr | 3 | Ho | <0.01 |
| Si | 2.00E+03 | Nb | <0.1 | Er | <0.01 |
| P | * | Mo | <0.1 | Tm | <0.01 |
| S | * | Ru | <0.1 | Yb | <0.01 |
| K | <10 | Rh | <0.1 | Lu | <0.01 |
| Ca | <1 | Pd | <0.1 | Hf | <0.01 |
| Sc | <1 | Ag | <0.1 | Ta | <0.01 |
| Ti | <1 | Cd | <0.01 | W | <0.01 |
| V | <1 | In | <0.01 | Re | <0.01 |
| Cr | <1 | Sn | <1 | Os | <0.01 |
| Mn | <1 | Sb | <1 | Ir | <0.01 |
| Fe | <1 | Te | <0.01 | Pt | <0.01 |
| Co | <1 | I | <0.01 | Au | <0.01 |
| Ni | <1 | Cs | <0.1 | Hg | <0.01 |
| Cu | <1 | Ba | <1 | Tl | <0.01 |
| Zn | <1 | La | <0.1 | Pb | <1 |
| Ga | 7 | Ce | 3.00E+02 | Bi | <0.1 |
| Ge | <0.1 | Pr | <0.01 | Th | <0.01 |
| As | <0.1 | Nd | <0.01 | U | <0.01 |

In Table 2, the elements denoted by the symbol “*” are main components or acid components used for decomposition, and are not the data to be analyzed. The sign “<” represents that the numerical values next to the sign are less than the quantitative lower limit.

### Example 4

A garnet compound to be obtained in Example 4 was also “(Y_{0.98}Ce_{0.02})₃Al₂(AlO₄)₃” having a garnet-type crystal structure. The garnet compound was obtained in the same manner as Example 1 except that the temperature for the main baking was changed to 1400° C.

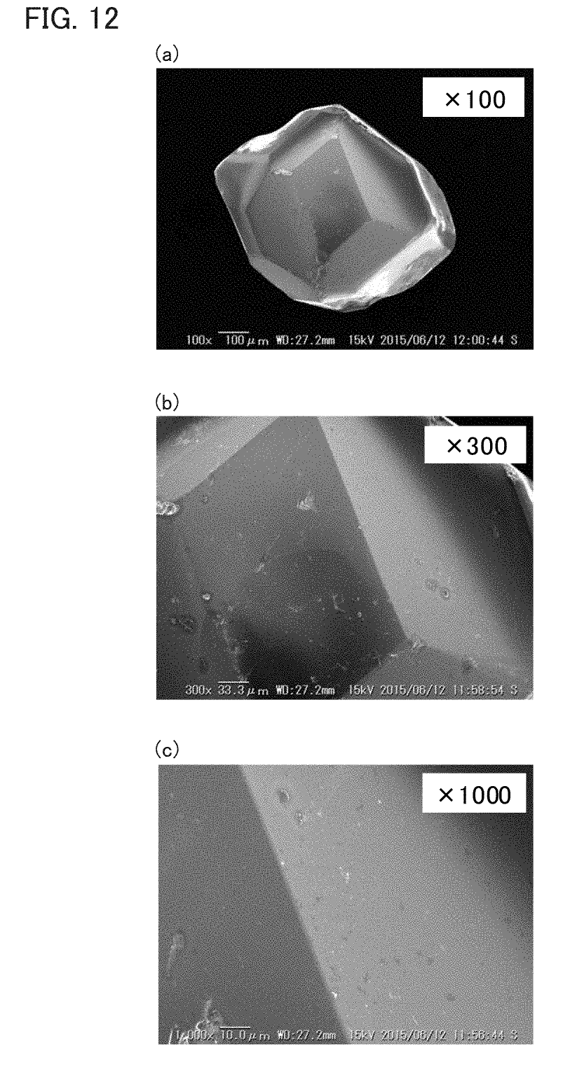

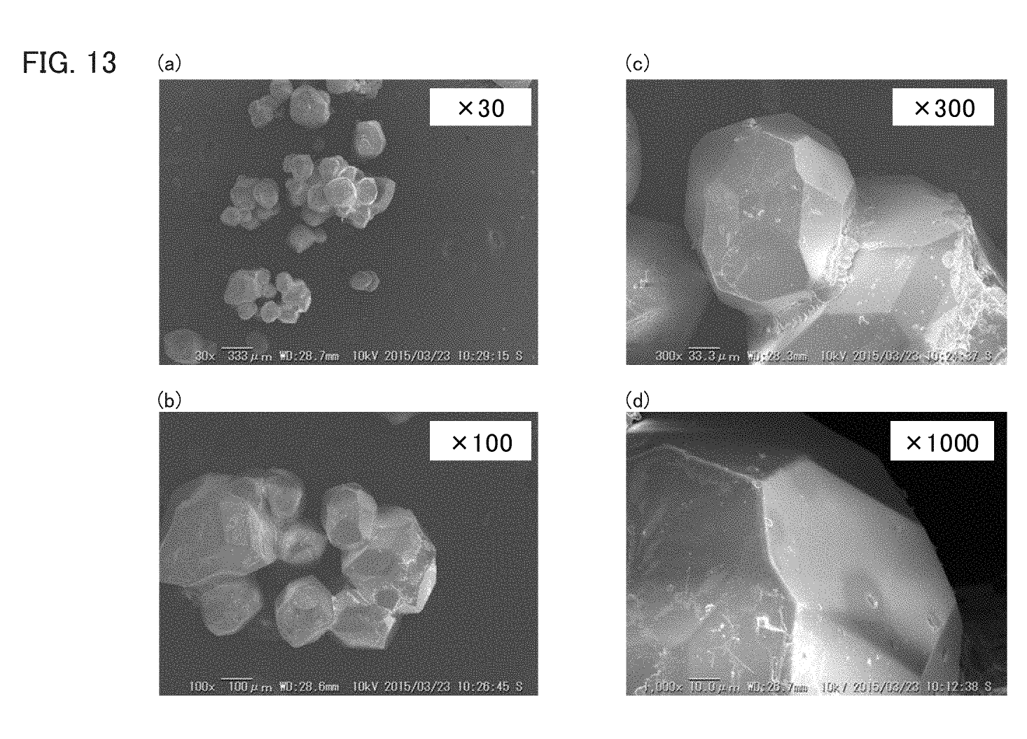

The garnet compound of Example 4 was also observed with the electron microscope in the same manner as Examples 1 to 3. FIG. 12 shows the garnet compound after washing, and FIG. 13 shows the garnet compound before washing. As shown in FIG. 12, the garnet compound of Example 4 has a particle size of about 860 μm. The garnet compound of Example 4 has a particle shape approximate to a rhombic dodecahedron provided with clear facets. As shown in FIG. 13, the garnet compound of Example 4 before washing includes a single particle having a particle shape derived from a crystal structure of garnet, and includes an aggregation in which such single particles are aggregated.

As described above, the primary particle in the garnet compound according to the present embodiment is a large monodisperse particle and has facets as shown in FIG. 12. Thus, the garnet compound according to the present embodiment can be regarded as a particle aggregation of single crystals having a high crystal grade. Analysis further revealed that, according to Example 4, the increase in the temperature for the main baking (the synthesis temperature) can increase the particle size, so as to synthesize at least approximately millimeter-sized compound particles.

The crystal structure of the garnet compound of Example 4 was also analyzed in the same manner as Example 1. When the emission spectrum of Example 4 was measured, the same result as Example 1 was obtained.

### Example 5

A garnet compound to be obtained in Example 5 was “(Y_{0.68}Gd_{0.30}Ce_{0.02})₃Al₂(AlO₄)₃” having a garnet-type crystal structure. The garnet compound of Example 5 was obtained in the same manner as Example 1 except that the respective raw materials were weighed in the mixing ratios for Example 5 shown in Table 1.

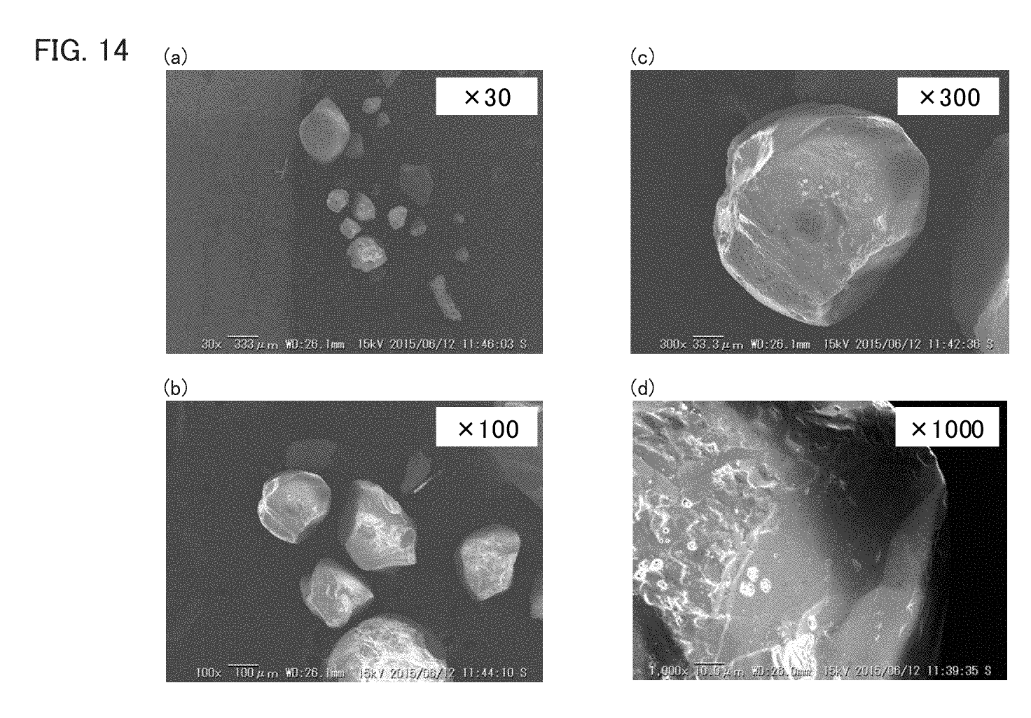

The garnet compound of Example 5 was observed with the electron microscope in the same manner as Examples 1 to 3. As shown in FIG. 14, the garnet compound of Example 5 after washing also includes a monodisperse particle which is recognized as having facets derived from a crystal structure of a garnet compound. The particle size of the garnet compound was about 260 The garnet compound of Example 5 also resulted in a large monodisperse particle on which facets were observed.

### Example 6

A garnet compound to be obtained in Example 6 was “(Y_{0.98}Ce_{0.02})₃Al₂(AlO₄)₃” having a garnet-type crystal structure. The garnet compound of Example 6 was obtained in the same manner as Example 1 except that the respective raw materials were weighed in the mixing ratios for Example 6 shown in Table 1 and the baking temperature was changed to 1000° C.

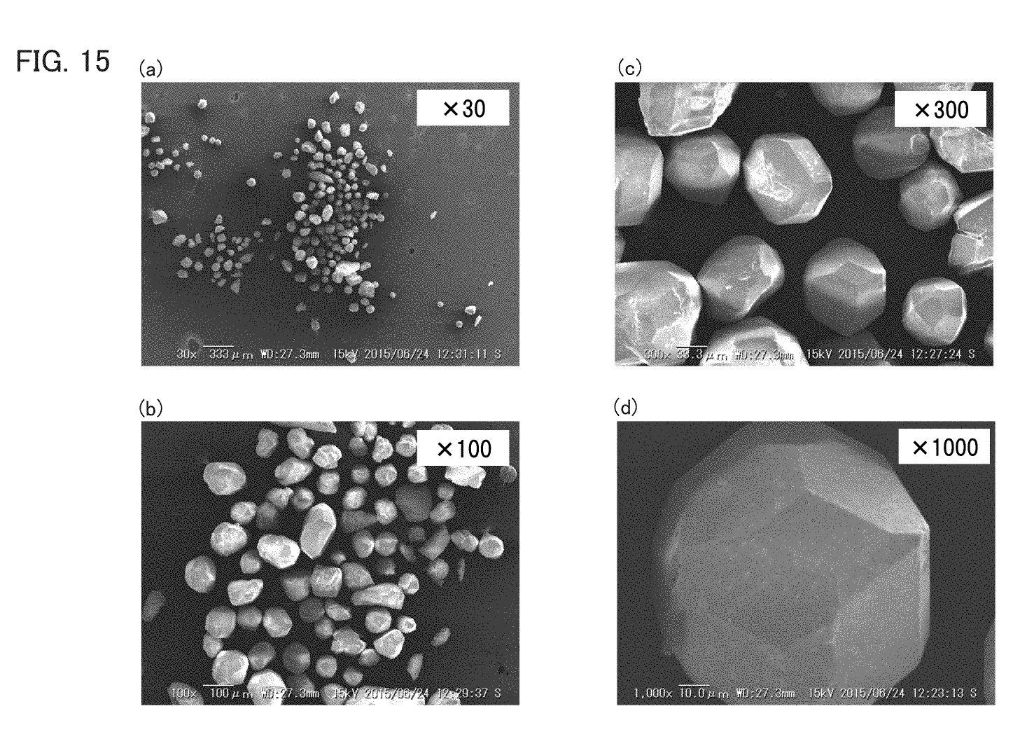

The garnet compound of Example 6 was observed with the electron microscope in the same manner as Examples 1 to 3. As shown in FIG. 15, the garnet compound of Example 6 after washing also includes a monodisperse particle which is recognized as having facets derived from a crystal structure of a garnet compound. The particle size of the garnet compound was about 90 The garnet compound of Example 6 excluding Al₂O₃ as a raw material also resulted in a large monodisperse particle on which facets were observed.

As described above, the garnet compounds of Examples 1 to 6 produced do not use a conventionally-known flux method or do not use a lead compound (such as PbO and PbF₂) serving as flux. The garnet compounds do not even include a lead compound as a raw material. Thus, the amount of the lead compound in the garnet compounds of Examples 1 to 6 measured by wavelength-dispersive X-ray fluorescence spectroscopy is less than 1 ppm.

The lead content of the Y₃Al₂(AlO₄)₃ compound produced by a conventionally-known flux method was also measured, and the result was about 0.5 mass % (about 5000 ppm).

The entire content of Japanese Patent Application No. P2015-144595 (filed on Jul. 22, 2015) is herein incorporated by reference.

While the present embodiment has been described above with reference to examples and comparative example, the present embodiment is not intended to be limited to the descriptions thereof, and various modifications can be made within the scope of the present embodiment.

### INDUSTRIAL APPLICABILITY

The present invention can provide a garnet compound causing little damage to the environment and including a single crystal with a large particle size without iron contained as a main component. The method for producing the garnet compound can reduce damage to the environment because the method does not require a lead compound used as flux. The light emitting device including the garnet compound can ensure light emission characteristics with high efficiency. The use of the garnet compound as a decorative material for a decorative article can improve its appearance. The garnet compound can be used as fluorescent sand to serve as a detected object with high reliability for a long period of time.

### REFERENCE SIGNS LIST

2 PHOSPHOR
   100 SEMICONDUCTOR LIGHT EMITTING DEVICE (LIGHT EMITTING DEVICE)
   200 DECORATIVE ARTICLE

1. A garnet compound comprising a single particle or an aggregation of single particles, each single particle having a particle shape derived from a crystal structure of garnet, and having a composition represented by a general formula:
A′₃B′₂(C′X₄)₃ (1)
where A′, B′, and C′ are cations forming the garnet compound, and X is an anion forming the garnet compound, neither B′ nor C′ contains iron as a main component,
wherein the single particle has a particle size categorized as sand in geology, and
a content of lead is 1000 ppm or less.

2. The garnet compound according to claim 1, wherein at least one element selected from the group consisting of Hg, Bi, TI, Sb, Sn, Fe, Mn, Cr, B, Ba, Cd, Te, Se, As, Be, In, Ni, Co, and V is contained in an amount of 1000 ppm or less.

3. The garnet compound according to claim 1, wherein the single particle has a facet.

4. The garnet compound according to claim 1, wherein the garnet compound is a rare earth compound.

5. The garnet compound according to claim 4, wherein the garnet compound is rare earth aluminum garnet.

6. The garnet compound according to claim 1, wherein the garnet compound emits fluorescence.

7. The garnet compound according to claim 6, wherein the garnet compound absorbs visible light having a short wavelength of 380 nm or greater and less than 480 nm and converts the short-wavelength visible light into visible light having a longer wavelength than the short-wavelength visible light.

8. The garnet compound according to claim 7, wherein the garnet compound is a phosphor activated by Ce³⁺.

9. A method for producing the garnet compound according to claim 1, the method comprising a step of reacting at least a rare earth halide-based compound containing a rare earth element and halogen with an oxide-based compound containing oxygen.

10. The method according to claim 9, wherein the rare earth halide-based compound is rare earth fluoride, and the oxide-based compound contains at least an alkali metal compound.

11. A method for producing the garnet compound according to claim 1, the method comprising a step of reacting at least fluoride with an alkali metal compound.

12. A light emitting device comprising the garnet compound according to claim 6.

13. A decorative article comprising the garnet compound according to claim 1 as a decorative material.

14. A method of using the garnet compound according to claim 1 as a decorative material or fluorescent sand.
